(19) United States
(12) Patent Application Publication
(10) Pub. No.: US 2025/0102702 A1
(43) Pub. Date: Mar. 27, 2025

(54) Space Weather Measurement Systems and Methods

(71) Applicant: Aspect Aerospace LLC, Mobile, AL (US)

(72) Inventors: Edmund Spencer, Mobile, AL (US); Samuel Russ, Mobile, AL (US); Andrew Russ, Mobile, AL (US)

(21) Appl. No.: 18/664,407

(22) Filed: May 15, 2024

Related U.S. Application Data
(60) Provisional application No. 63/608,148, filed on Dec. 8, 2023.
(60) Provisional application No. 63/540,838, filed on Sep. 27, 2023.

(51) Int. Cl. G01W 1/10; G01N 27/02

(52) U.S. Cl. CPC G01W 1/10; G01N 27/02

(57) ABSTRACT

Embodiments include a system for measuring a physical phenomenon using a plurality of satellites. The system can include a controlling station and a first satellite. The first satellite can comprise a communication interface, a command and data handling (“C&DH”) computer, and a probe device. The C&DH computer can be configured to perform operations including receiving, from the controlling station, first measurement parameters, and providing, using the communication interface, the first parameters to the probe. The probe can be configured to perform: receiving, using the communication interface, the first parameters; measuring the physical phenomenon using the first parameters and collecting measurement data. The probe can process the collected data and apply data compression selectively to the processed collected data based on one or more of the first parameters and/or a determined significance of the processed collected data. The probe device can also apply encryption selectively to the processed collected data with the selectively applied data compression to generate selectively compressed and selectively encrypted measurement data, which it can transfer, using the communication interface, to another device on the satellite that can be configured to transmit to the controlling station the selectively compressed and selectively encrypted measurement data. The controlling station can receive and analyze the selectively compressed and selectively encrypted measurement data from the first satellite to determine the existence of an anomaly at one or more locations in space, and determine one or more second measurement parameters different from the said first parameters and configured to cause a second satellite to perform additional measurements targeting the anomaly. The controlling station can transmit the second parameters to the second satellite, which can be configured to perform additional measurements targeting the anomaly based on the second parameters.

This application claims the benefit of U.S. Provisional Application No. 63/540,838, entitled “Space Weather Measurement System” and filed on Sep. 27, 2023, which is incorporated herein by reference in its entirety. This application also claims the benefit of U.S. Provisional Application No. 63/608, 148, entitled “Space Weather Measurement System” and filed on Dec. 8, 2023, which is also incorporated herein by reference in its entirety.

Human-made satellites in space have become essential to modern commerce. For example, GPS satellites provide worldwide location services that are used countless number of times per day. Other examples include weather satellites and satellites that photograph the Earth's surface. Because of their economic utility, it is important to understand the atmosphere surrounding satellites in order to protect their operation. The atmosphere surrounding satellites is formed of plasma, a state of matter similar to gas but in which atoms are ionized. The term “space weather” refers to the condition of this atmosphere and is constrained by, among other parameters, the density, temperature, and composition of the plasma.

While probes and sensors have been developed to measure plasma density and temperature at specific points in space, it is still the case that the state of the plasma generally is inferred from solar activity. While physically plausible (such activity has substantive effects on plasma density and temperature), it lacks accuracy and specificity. Other methods, such as measuring radio signals between a satellite and GPS satellite or between a satellite and the ground, do not measure plasma directly near the satellite itself.

Recently, a sensor to measure plasma density locally and at a very high rate of speed has been developed. The so-called Time Domain Impedance Probe can make a single plasma-density measurement in 100 microseconds. When travelling at the speed of an orbiting satellite, this reduced time also results in a measurement of extremely high spatial resolution, and permits direct detection of plasma fluctuations, a condition known as scintillation.

However, this comes at a cost-the sensor is capable of generating voluminous amounts of data as it measures plasma density. Systems and methods may be needed to manage the operation of such a sensor in order to improve data handling, preserve the fidelity of the measurement, and/or protect its commercial value. Further, a constellation of satellites bearing such sensors could be used to construct a detailed, real-time, three-dimensional map of plasma properties, and so systems and methods may be needed to manage such a constellation. Further, a satellite bearing such a sensor could benefit from the information gathered by the sensor, and so systems and methods may be needed to manage the interface between the sensor and the rest of the satellite.

One example of an instrument that can measure plasma density is the Time Domain Impedance Probe (TDIP), an instrument that is capable of making a single plasma-density measurement in 100 microseconds. This results in a voluminous data rate of measurements in the time domain and, after applying a Fast Fourier Transform, in the frequency domain. Even if resolved to a single density measurement, the sustained data rate of the instrument is very high for a spaceborne instrument.

Note that the TDIP is but one example of a spaceborne instrument. The term “instrument” as used here and below refers generally to a spaceborne instrument that makes regular measurements, can generate voluminous amounts of data (which can be more than can be readily transmitted to Earth in the satellite that hosts it), and that has a controllable data-gathering rate or controllable resolution.

It is an object of one or more embodiments of the present disclosure to manage the volume of data produced by the instrument. With the careful application of various forms of data compression, the amount of bandwidth needed to send data to Earth can be carefully controlled, and a trade-off between accuracy and data rate can be made.

It is an object of one or more embodiments of the present disclosure to repurpose an instrument designed to gather data in order to use the data to protect the satellite itself and to permit the satellite to operate correctly and to operate as fully as possible.

It is an object of one or more embodiments of the present disclosure to manage the confidentiality of the data produced by the instrument. A first operator may operate the instrument and a second may operate the satellite that houses the radio used to send the instrument data back to Earth. Selective encryption methods may be configured so that the first operator can retain control of access to the data and thereby obtain revenue. The second operator may require access to some of the data, for example in order to manage the satellite, and so there may be a need for careful control of the cryptographic methods that are employed.

It is an object of one or more embodiments of the present disclosure to control the flow of data out of the instrument. For example, the satellite itself may access alerts of plasma conditions that may endanger the satellite or hamper its ability to function. Some information generated by the instrument may be more urgent in nature and so may preferably be transmitted to a ground station when one is available. Other information may be less urgent but of significant scientific value. In such systems, a need may exist for a system of data management.

It is an object of one or more embodiments of the present disclosure to control a constellation of satellites bearing such instruments. A coarse measurement made by one satellite might indicate the need for subsequent passes through the same volume of space to be made at a higher resolution. Ground control may be able to vary the cadence, degree of data compression, and/or degree of encryption dynamically as measurements are made by multiple satellites.

Changes to satellite orbit may be possible in some circumstances.

It is an object of one or more embodiments of the present disclosure to manage the data-gathering efforts of a constellation of satellites in order to gather the data into a coherent, detailed model of plasma density. The data-gathering properties can be altered in near-real-time to explore plasma anomalies at high spatial and/or temporal resolution.

It is an object of one or more embodiments of the present disclosure to use point-based data from satellites to interpolate into a model of a volume of near-earth space (e.g., the entire volume of near-earth space).

### BRIEF DESCRIPTION OF THE DRAWINGS

FIG. 1 is a diagram of an example satellite showing an example satellite configuration, in accordance with some implementations.

FIG. 2 is a flowchart of an example method of processing measurements using a TDIP sensor, in accordance with some implementations.

FIG. 3 is diagram of an example TDIP sensor, in accordance with some implementations.

FIG. 4 is a diagram of an example satellite configured to include a TDIP sensor and showing an example interface configuration between the TDIP sensor and other components of the satellite, in accordance with some implementations.

FIG. 5 is a diagram of an example satellite ground station, in accordance with some implementations.

FIGS. 6A-C are diagrams of an example of constellation management, in which a

measurement made by one sensor is used to control the data-gathering parameters of a second sensor, in accordance with some implementations.

FIG. 7 is a flowchart of an example method associated with the application of data compression, in accordance with some implementations.

FIG. 8A is a diagram of an example of satellites making measurements in situ, in accordance with some implementations.

FIG. 8B is a diagram of an example of satellites making measurements using radio occultation that are cumulative across the line of travel of the radio signal, in accordance with some implementations.

### DETAILED DESCRIPTION

The following description is presented in order to enable persons of ordinary skill in the art to make and use embodiments of the present disclosure. Various modifications to the disclosed embodiments will be readily apparent to persons of ordinary skill in the art, and the principles disclosed herein are applicable to other embodiments of the present disclosure without departing from the spirit and scope of the present disclosure. The present disclosure explicitly discloses that there are numerous combinations and embodiments of elements, and all combinations are therefore disclosed herein.

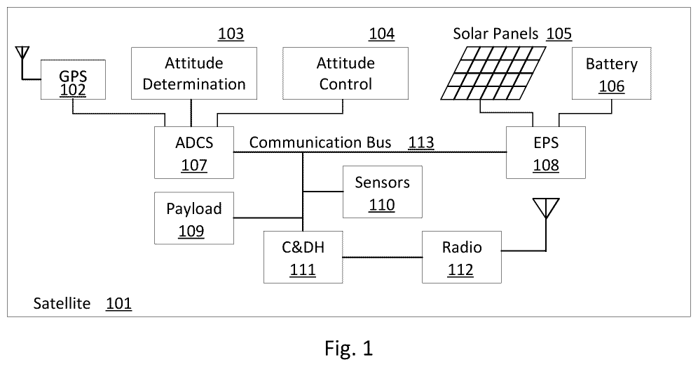

FIG. 1 is a diagram of an example satellite 101 showing an example satellite configuration, in accordance with some implementations. Satellite 101 includes a GPS receiver 102, an attitude determination system 103, an attitude control system 104, solar panels 105, batteries 106, an attitude determination and control system (ADCS) 107, an electrical power system (EPS) 108, a payload 109, sensors 110, a command and data handling computer (C&DH) (or “on-board computer (OBC)” or “primary flight computer”) 111, a radio 112, and a communication bus 113. Satellite 101 includes components to operate in orbit/space. In operation, GPS receiver 102 can be configured to determine the current position of satellite 101 in space. Note that GPS is only functional up to a certain altitude and, above that altitude, other navigational systems/methods can be used. Attitude-determination system 103 can be configured to enable the satellite 101 to measure its orientation in space. Sensors that can be used for this purpose include magnetometers, rate gyroscopes, and star trackers. Attitude control system 104 can be configured to control the orientation of satellite 101. Devices such as magnetorquer rods, reaction wheels, and thrusters can be used. Note that thrusters can also be used to change the orbit and/or trajectory of satellite 101 through space. Attitude determination and control system (ADCS) 107 can include a computer system that can be configured to determine and control attitude. Electrical power system (EPS) 108 can be configured to manage electric power (e.g., managing and monitoring battery charge). In some embodiments, EPS 108 can be configured to use solar panels 105 and batteries 106 as part of its management. Besides managing and monitoring battery charge, EPS 108 can also be configured to power down and power up individual components as needed. The primary flight computer of satellite 101, shown as command and data handling (C&DH) computer (or “on-board computer (OBC)”) 111, can be configured to manage overall operations of satellite 101. Satellite 101 includes one or more radios, shown as radio 112, to communicate with Earth. The flow of data from satellite 101 to Earth, called the downlink, can be used to convey measurements and information about the health and state of satellite 101. The flow of data from Earth to satellite 101, called the uplink, can be used to control the operations of satellite 101. In some embodiments, satellite 101 contains multiple radios. For example, one radio may have an omnidirectional antenna and a lower data rate and another radio may have a directional antenna and a higher data rate. In such a situation, the lower-data-rate radio may be used for low-bitrate operations like transmitting satellite health information and receiving commands while the higher-data-rate radio can be used to downlink payload data, such as images. Attitude determination system 103 can be configured to manage aiming the directional antenna (or even the entire satellite 101) to manage the directional antenna's operation while flying over a ground station. Conversely, by not having to be aimed, the radio with the omnidirectional antenna is more reliable in the sense that it is nearly always operational, even if attitude determination system 103 is inoperative, flawed, or has not gained complete control of attitude. This reliability is another reason why satellite health and commands are often transmitted over a lower data rate radio.

Every satellite is launched for some purpose (or purposes). Generally, the element of the satellite that represents its purpose is called the payload, shown in FIG. 1 as payload 109. For example, the payload of a weather satellite can be cameras that photograph clouds. Satellite 101 can include other sensors 110 as well, the nature of which are dictated by the mission of the satellite. For example, a space probe might carry a specialized magnetometer or radiation sensor as sensors 110 in some embodiments.

Communication bus 113 can be configured to connect the various components of satellite 101 so that they can interoperate correctly. In some embodiments, communication bus 113 includes a plurality of individual buses and can represent a plurality of communications methods and protocols. In some embodiments, one component may only communicate with a single other component, relying on the other component to provide connectivity to communications bus 113.

All the parts of a satellite except the payload are broadly referred to as the “bus” of the satellite, but the terms “bus” and “payload” are generally used broadly. Most of the time the “payload” is distinct from the “bus”. For example, one company may manufacture a bus that a payload manufacturer can purchase and use. However, the distinction between them is relatively unimportant.

Most satellites orbit the Earth. Satellites near Earth are considered to be in low earth orbit (LEO) or very low earth orbit (VLEO). Some satellites, such as communications satellites, are in geosynchronous orbit (GEO) and, in between, satellites can be in middle earth orbit (MEO).

Satellites in LEO or VLEO are in a region of relatively high plasma density; they are orbiting just above Earth's atmosphere. As a result, increases in plasma density, such as by heating due to increased solar activity, can cause the orbits of such satellites to decay more rapidly. Indeed, some satellites have been lost due to this phenomenon.

Satellites in GEO are vulnerable to solar events, such as coronal mass ejections (CMEs) because they orbit above the protection of the Van Allen belts, structures that trap plasma and protect lower altitudes.

At least one class of satellites in MEO, navigation satellites such as those that provide GPS signals, are sensitive to plasma. One important reason is that the GPS signals transmitted by the satellites travel through the plasma to Earth, and so effects such as scintillation can affect the accuracy of GPS.

As a result, the parameters of the plasma itself, such as density and temperature, are vitally important to satellites. That is, each individual satellite may benefit from local plasma measurements. For example, detecting a higher-than-normal plasma density may enable a satellite to go into a protective “safe mode” by shutting down non-essential functions or to go into a “station-keeping” mode by boosting its orbit. Further, if data is collected from multiple satellites, it becomes possible to develop a global, real-time, three-dimensional map of the plasma.

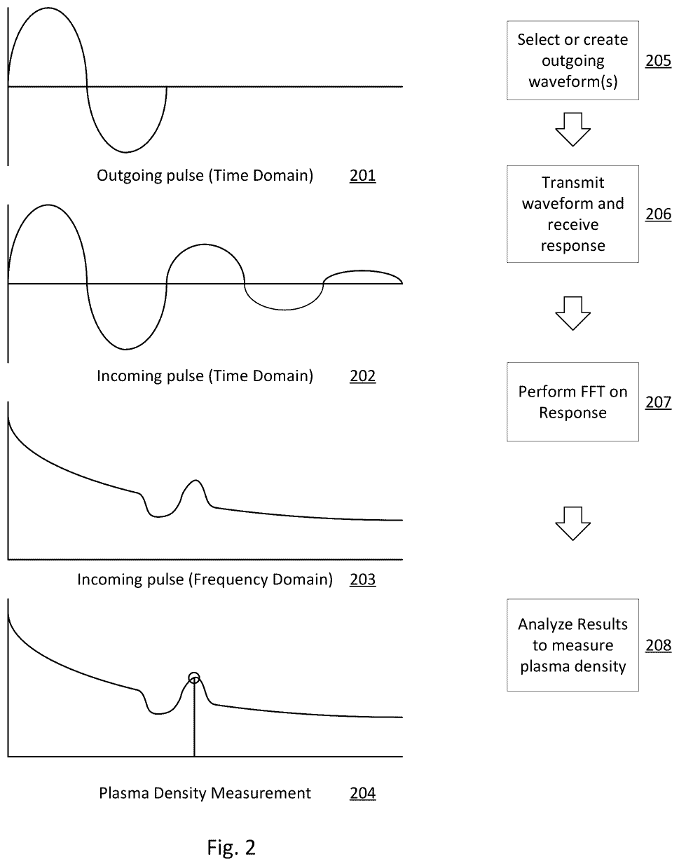

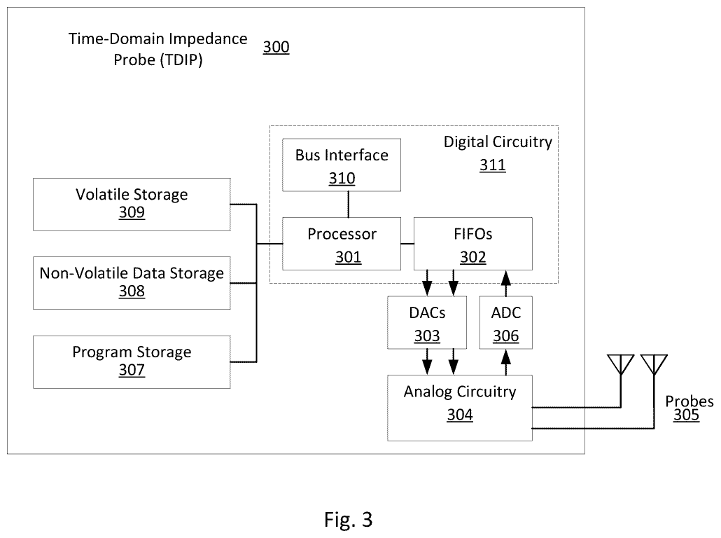

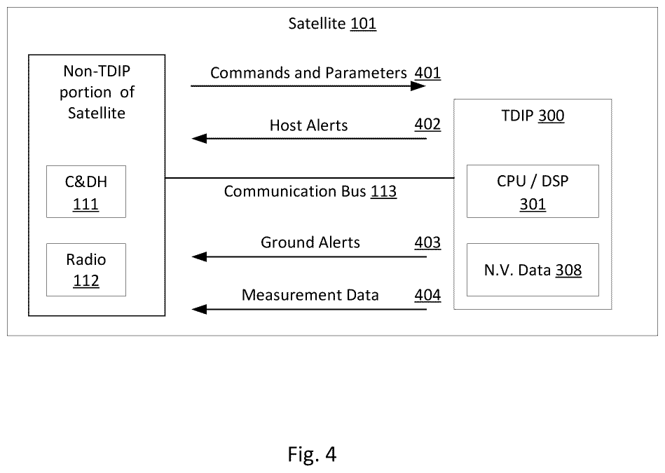

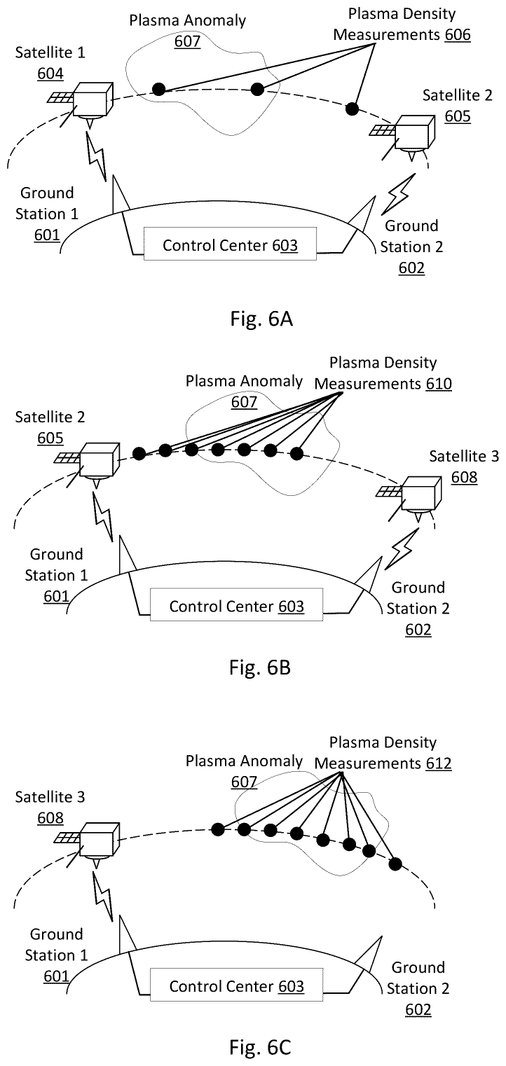

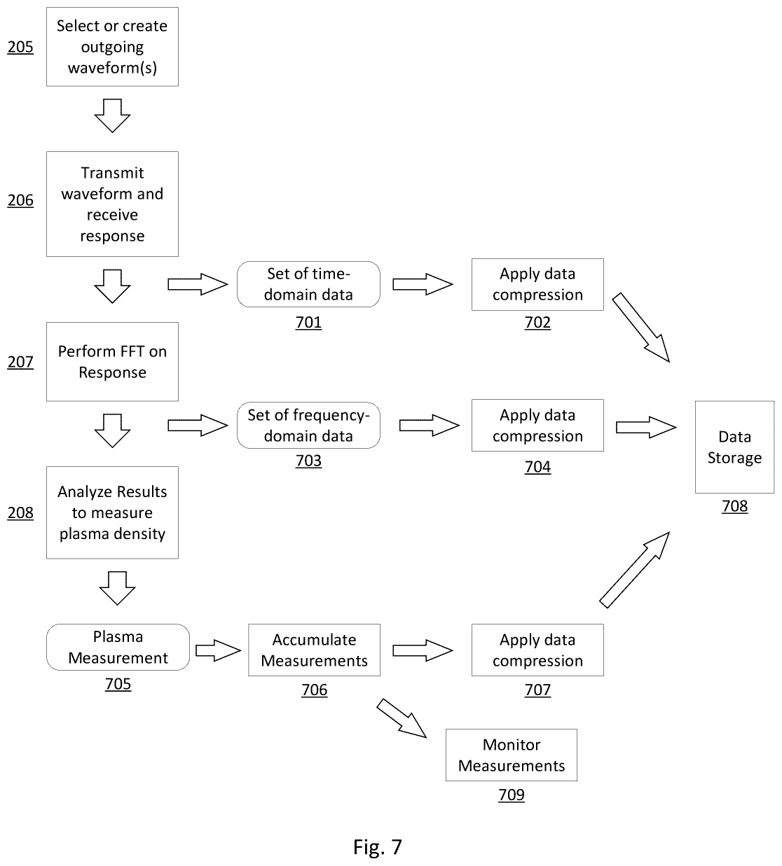

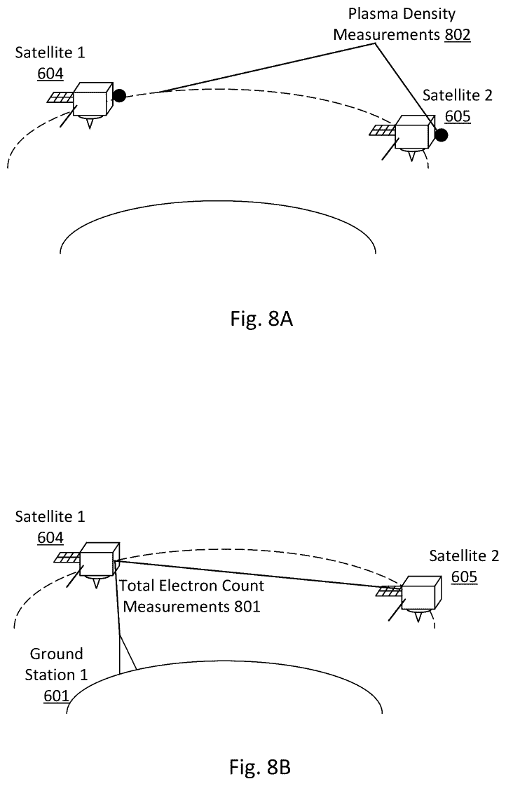

One way to better understand plasma is to build and use a sensor/probe to measure it. One such sensor is the time domain impedance probe (TDIP). In some embodiments, the sensors 110 can include a TDIP such as that shown in E. Spencer et al., “First results from a time domain impedance probe for measuring plasma properties in the ionosphere,” 2017 IEEE 60th International Midwest Symposium on Circuits and Systems (MWSCAS), Boston, MA, USA, 2017, pp. 1284-1287, doi: 10.1109/MWSCAS.2017.8053165, and/or E. Spencer, D. Clark and S. K. Vadepu, “A Time-Domain Impedance Probe for Fast Measurements of Electron Plasma Parameters in the Ionosphere,” in IEEE Transactions on Plasma Science, vol. 47, no. 2, pp. 1322-1329 February 2019, doi: 10.1109/TPS.2018.2890336, each of which is hereby incorporated by reference herein in its entirety as if fully set forth herein. In some such embodiments, such a TDIP can, in operation, be configured to perform measurement processing 205-208 shown in FIG. 2 and described hereinbelow, perform the selective compression processing 701-709 shown in FIG. 7 and described hereinbelow, perform the selective encryption processing described hereinbelow, and/or perform processing associated with any of FIGS. 6 and 8 and described herein with respect to the figures. The TDIP can also be configured as shown for TDIP 300 in FIGS. 3 and 4 and discussed in detail hereinbelow.

FIG. 2 is a flowchart of an example method of processing measurements using a TDIP sensor (e.g., TDIP 300 shown in FIG. 3 and described hereinbelow), in accordance with some implementations. Processing begins at 205, where the probe selects or creates an outgoing waveform (or waveforms). The waveform is generated from a series of numerical values, each of which is converted to an analog voltage using the method of digital-to-analog conversion well known in the art. The individual numeric values are not shown. Because the outgoing waveform created in step 205 originates in the digital domain, the TDIP can change the outgoing pulse to any pulse that the digital-to-analog conversion process is capable of generating. The waveforms may be stored ahead of time (e.g. in non-volatile data storage) or may be generated algorithmically as needed. In one exemplar embodiment, the samples are emitted at a rate of 60 megasamples per second and each sample is a 12-bit integer number in the digital domain. One waveform spanning 102.4 microseconds requires 6, 144 12-bit samples or 9,216 bytes of storage.

The TDIP performs digital-to-analog conversion, resulting in an analog waveform such as outgoing pulse 201. In the embodiment shown, outgoing pulse of voltage 201 has an equal amount of energy above and below the axis, producing the desirable property of zero DC energy. Zero DC energy results in the probe neither charging nor discharging the antenna.

In the example voltage waveform 201, a “double pulse” is shown because it maximizes the frequency content while keeping the DC energy at zero. Importantly, the pulse waveform has signal energy from near DC to very high frequencies, presenting such frequencies to the plasma at once. This double pulse might be formed from sinusoids or a derivative-Gaussian waveform. Other waveforms are possible, such as sinusoidal waveforms that transmit energy at a single frequency. The nature of the waveforms selected can be controlled to meet desirable physical properties. For example, some waveforms may have different frequency-domain properties or have zero DC energy. One skilled in the art is able to select among various waveforms so as to meet specific performance or measurement goals. Processing continues to 206.

At 206, the TDIP transmits the waveform (e.g., outgoing pulse of voltage 201) on an antenna into the plasma surrounding the satellite and, at the same time, receives a response. The TDIP thus receives an altered, incoming voltage pulse 202 from the same antenna. The change in the waveform is due to the effects of the plasma surrounding the satellite (or, more specifically, the plasma surrounding the antenna structure.) In other words, the incoming voltage pulse 202 has been affected by the plasma and therefore properties of the plasma can be discerned from it. For example, the incoming voltage pulse 202 can be reflected back from the plasma. The time-domain waveform can be sampled and converted to numeric information using the well-known method of analog-to-digital conversion. In one exemplar embodiment, the waveform is sampled at a rate of 40 megasamples per second and each sample is a 12-bit integer number in the digital domain. Processing continues to 207.

At 207, using the well-known Fast Fourier Transform (FFT), the sequence of digitized samples can be converted to a frequency-domain representation resulting in frequency data 203. Because of the properties of the waveform and of the plasma, this curve slopes downward with two perturbations in the example shown by frequency data 203. Processing continues to 208.

At 208, the data from the FFT (the data in the frequency-domain curve 203) can be analyzed resulting in a single plasma-density measurement, illustrated graphically in 204.

In this embodiment, a single incoming pulse is digitized into 4096 samples. Because of the sample rate of 40 megasamples per second, the entire pulse has a duration of 102.4 microseconds, or about 100 microseconds. The reciprocal of 100 microseconds is 10 kilohertz. Stated differently, the instrument in this embodiment is capable of about 10,000 measurements per second.

To recap, one outgoing waveform consists of 6144 12-bit samples, which is 9216 bytes of data. For embodiments with two outgoing waveforms, the total storage needed is 18432 bytes. The incoming waveform consists of 4096 12-bit samples, which is 6144 bytes of data. Because of the nature of the Fast Fourier Transform, the frequency-domain representation is the same size. The measurement process yields a single frequency which, because of the FFT, has a 12-bit resolution. With interpolation, the single frequency represents roughly 15 bits of information. When multiplied by the cadence of the measurement, the instrument yields about 60 megabytes, or 480 megabits, of time-domain data per second and about 150 kilobits per second of density measurements. The outgoing data rate is a function of whether the same waveform is used repetitively.

In some embodiments, the time-domain waveform obtained in step 206 is transmitted to Earth for analysis, such as the FFT 207 and subsequent analysis 208. In other embodiments, the FFT 207 and subsequent analysis 208 can be performed by the TDIP itself (e.g., without needing to be transferred to earth for analysis at a ground station or control center).

There are other sensors and methods for measuring plasma density and composition. For example, a frequency-sweep sensor emits radio energy at multiple frequencies, often by “sweeping” from one frequency to another. This sensor also measures the properties of the plasma at different frequencies and so infers plasma density from a frequency-domain measurement. Also, like TDIP, it makes a measurement at a specific location, namely in close physical proximity to the satellite housing the instrument.

Another method is to measure the phase shift in a well-understood radio signal, a method called radio occultation. This results in a measurement of total electron count, but accumulated over the entire length of the radio signal. In other words, it makes a cumulative measurement over an entire path rather than measurement at a specific point in space.

An embodiment of the time-domain impedance probe is shown in FIG. 3. FIG. 3 is diagram of an example time-domain impedance probe (TDIP) 300, in accordance with some implementations. The TDIP 300 includes one or more digital-to-analog converters (DACs) 303, analog circuitry 304, probes 305, analog-to-digital converter (ADC) 306, program storage 307, non-volatile storage 308, volatile storage 309, and digital circuitry 311 which includes processor 301, one or more first in first out queues (FIFOs) 302, and bus interface 310. In operation, processor 301 may execute code stored in program storage 307. Code stored in program storage 307 can include software instructions that, when executed by the processor 301, cause the processor 301 to perform operations for plasma measurement processing in accordance with the present disclosure (e.g., performing a portion or all of one or more of the processing shown in FIGS. 2 and 7) that is used to manage the sensor's operations. The processor 301 may include one or more CPU cores, DSP elements to accelerate the FFT, and may include a floating-point unit (FPU) or GPU to accelerate other computations. The processor 301 may also include elements to accelerate cryptographic operations such as a high-speed encryptor/decryptor unit. It may include additional elements such as a direct memory access (DMA) controller, dynamic RAM (DRAM) controller, timers, interrupt controllers, watchdog timers, etc. The processor may be implemented as a single core, multiple cores, and/or a combination of CPU cores and more specialized elements, such as DSP, FPU, GPU, and crypto processor.

In operation, the processor 301 can be configured to utilize FIFOs 302 to stage data through the analog section (e.g., 303-306). For example, one set of FIFOs 302 contains the digitized versions of the outgoing waveforms. In one embodiment, both the waveform sent to the antenna and a comparison waveform are sent out of the FIFOs 302. In one embodiment, the comparison waveform is identical to the outgoing waveform, and so subtraction stage (described further below) compares the version of waveform received back from the plasma to the original waveform. In this embodiment, the difference signal represents the modification made to the outgoing signal by the ambient plasma.

The digital-to-analog converters (DACs) 303 convert the outgoing waveforms into analog signals. These are fed into analog circuitry 304. This circuitry may include low-pass filtering for anti-aliasing, an appropriate level of gain to produce the correct voltages, and drive strength sufficient to drive the analog signals onto the probes 305. In one embodiment, one probe is connected to ground and the other is used to drive the analog waveform. In some embodiments, the probes are on the order of a half-meter long and protrude outside the body of the satellite. They can be constructed from simple material such as a metal measuring tape to enable the probes to both fold and deploy. The length of the probes can be adjusted as needed depending on desirable electrical properties. In one embodiment, each probe is about one meter long. One skilled in the art can select a probe length based on measurement accuracy, impedance, and compactness.

The analog circuit can perform functions on the incoming waveform such as additional gain or attenuation as needed. In the embodiment with two outgoing waveforms, the circuit can also subtract the comparison waveform from the incoming waveform.

The output of the analog circuitry, a single conditioned analog waveform, is then routed to analog-to-digital converter (ADC) 306 and fed into another FIFO 302. The processor 301 can then read the FIFO as needed to read the result. Generally, the processor 301 then performs the analysis described above in reference to FIG. 2.

If the processor 301 is not capable of processing an entire 100-microsecond measurement in 100 microseconds, parallelism can be employed. For example, if the processor 301 requires 300 microseconds to process a single measurement, three sets of data-processing elements can work in parallel, each alternately processing the next measurement.

The processor 301 connects to a bus interface 310 that connects the TDIP to the rest of the satellite. By its nature, the TDIP is usually connected to the C&DH computer 111. The bus interface can implement one or more well-known communication protocols including CAN, UART, SPI, I2C, Ethernet, and USB. A person of ordinary skill would recognize numerous additional possible protocols can be implemented. Multiple protocols can be employed simultaneously, such as a low-data-rate protocol for commands and status and a high-data-rate protocol for the TDIP plasma data.

Processor 301, FIFOs 302, and Bus Interface 310 are digital circuits. Thus, it is possible for digital circuitry 311 to be implemented as an application-specific integrated circuit (ASIC), multi-chip module, FPGA, gate array, a set of smaller integrated circuits, or any structure that can implement digital logic. The processor may employ instruction-executing CPUs, state machines, some other form of computer logic, or a combination. Similarly, analog circuitry 304 could be implemented as a multi-chip module, single analog ASIC, a set of smaller integrated circuits, or some combination of the two. DACs 303 and ADC 306 may be incorporated into a digital ASIC or analog ASIC or may lie between them. In some embodiments, various combinations of digital circuitry 311, DACs 303, ADC 306, Analog circuitry 304, and memories 307, 308, and 309 may be placed into a single multi-chip module. A variety of implementation strategies can be employed, and a person of ordinary skill in the art would be able to render the design in one of any number of ways. In addition, radiation-tolerant and/or radiation-hardened circuits may be employed to enable the TDIP 300 to operate more reliably in space.

Processor 301 has access to program storage 307 to access the software that controls the various elements of the processor (e.g. CPU cores, DSP, FPU, and/or GPU). This storage may be ROM (that is, permanent) or it may be reprogrammable. While flash memory is one possibility, magnetic RAM or MRAM is radiation-tolerant and could be used instead.

Non-volatile data storage 308 can be used to store both the outgoing waveforms in digital form and the data gathered by the sensor, including possibly time-domain, frequency-domain, and density data. The data gathered by the sensor can be stored, until it is transmitted to Earth, permitting the memory to be reused for additional data-gathering. Any reprogrammable non-volatile memory technology can be used, including flash, solid-state drives, and MRAM. One of ordinary skill would grasp the advantages and disadvantages of each. This storage may be separate from program storage 307 or it may be housed on the same storage device.

Volatile storage 309 is usable as RAM memory for the processor. It can be implemented as static RAM, dynamic RAM, or MRAM.

Two improvements to the TDIP design can be made.

First, the TDIP can alter the outgoing waveform by means of digital multiplication of the outgoing waveform by a constant value. Thus, the TDIP can attempt to transmit the same waveform at varying amplitudes. In one embodiment, the TDIP varies the amplitude and determines the highest amplitude that produces a linear plasma response. This feature, called automatic amplitude control (AAC), enables TDIP to operate over a wider range of plasma densities. If a measurement is needed at a particular place or time, the TDIP can begin the AAC process before the measurement time so that the actual measurement occurs at the correct moment. Note that amplitude can also be manipulated by analog means, such as a variable gain amplifier, with the same effect.

Second, circuitry can be added to the TDIP to permit calibration while in orbit. In one embodiment, a calibration circuit permits waveforms to be looped back to ADC 306 without being applied to the antenna. In another embodiment, a calibration circuit could permit the load of the antenna to be replaced by a circuit with a known frequency response.

FIG. 4 is a diagram of example satellite 101 configured to include TDIP 300 and showing an example interface configuration between TDIP 300 and other components of the satellite 101, in accordance with some implementations. In some embodiments, TDIP 300 is housed inside satellite 101, and its probes 305 (not shown in FIG. 4) extend outside the satellite 101. The “non-TDIP portion” of the satellite 101 and the TDIP 300, taken together, correspond to the satellite 101 shown in FIG. 1, with the sensors 110 including TDIP 300. In some embodiments, TDIP 300 can be replaced with some other type of plasma-density sensor, such as a frequency-sweep sensor, without departing from the scope of the present disclosure.

For example, radio 112 may receive commands from Earth that are forwarded to C&DH computer 111. These commands may be to alter the waveforms used by the TDIP 300, the cadence of measurements (e.g. slower than 10 kHz), the level of analysis to be performed, etc. The C&DH computer 111 then forwards the commands and parameters 401 over the communication bus 113 to TDIP 300. For example, new waveforms and updated measurement parameters may be stored in non-volatile data storage 308.

TDIP 300 may be programmed to issue host alerts 402 to the satellite itself. These host alerts 402 travel from the processor 301 of the TDIP 300 to the C&DH computer 111 of satellite 101. The C&DH computer 111 may be programmed to handle the alerts with appropriate actions, such as safe mode or station-keeping. The alerts may also be informational, such as notification that a set of measurements is complete or an update on the health of the TDIP 300.

Sometimes, the presence of significant events detected by TDIP 300 will need to be transmitted to Earth. For example, if the TDIP 300 detects a plasma anomaly (e.g. higher than expected density or a higher-than-expected rate-of-change of density), the processor 301 of the TDIP 300 may send a ground alert 403 to the C&DH computer 111 of satellite 101. The C&DH computer 111 is programmed to send the ground alert 403 via radio 112 to Earth. This ground alert then notifies control elements on Earth of one or more significant or noteworthy events. In other embodiments either host or ground alerts (or both) may be transmitted by radio 112 to other satellites in radio range.

The measurement data 404 detected by TDIP 300, such as plasma-density measurements or time-domain data, will need to be transmitted to Earth. The processor 301 of the TDIP 300 obtains the data from non-volatile data storage 308 and sends the data 404 to the C&DH computer 111 of satellite 101. The C&DH computer 111 is programmed to send the data 404 via radio 112 to Earth. This data can then be stored and/or processed. Once transmitted, the C&DH computer 111 may notify the TDIP 300 so that the data can be deleted from storage 308 and reused for subsequent measurements. In some embodiments, the measurement data 404 may be transmitted over a higher-data-rate radio while the ground alerts 403 may be transmitted over a lower-data-rate radio. As explained above in connection with radio 112, the lower-data-rate radio may be more reliable because of its omnidirectional antenna. The bus 113 may maintain two separate communication queues, one for ground alerts 403 and one for measurement data 404 because of the use of two radios or because of the desire to keep ground alerts at higher priority. The queues can be used to manage priority, giving ground alerts higher priority over measurement data, or can be routed to different radios, sending ground alerts to a different radio.

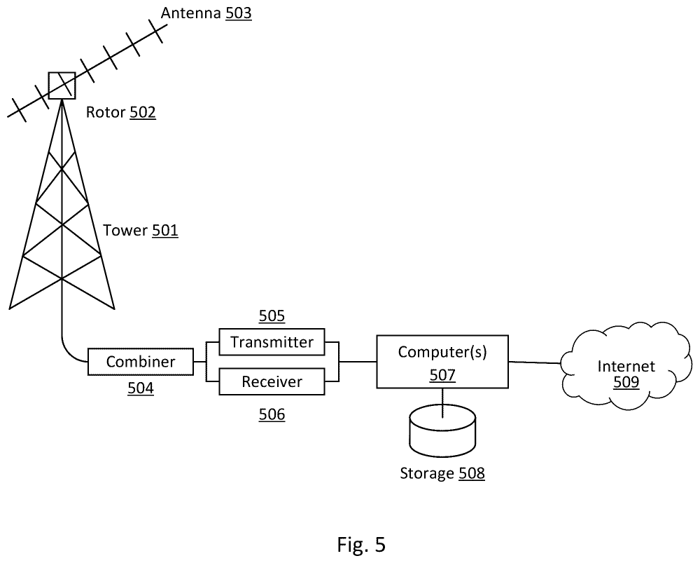

FIG. 5 is a diagram of an example ground station 500, in accordance with some implementations. Ground station 500 includes a combiner 504, transmitter 505, receiver 506, computer(s) 507, storage 508, internet connection 509, and a tower 501 that houses an antenna 503 mounted on a rotor 502. In operation, the rotor 502 can be used to aim the antenna 503 at a satellite of interest. The directionality of the antenna provides antenna gain, as is known in the art, and thereby boosts the strength of the signal that is received. A satellite, e.g. in LEO, only has line of sight to a relatively small amount of the Earth's surface. Conversely, a satellite will only be in view of (over the horizon of) a ground station for a few minutes at a time and only for a few times per day. The time duration and angle of view vary each time the satellite passes over, and knowledge of the satellite's orbit and the location of the ground station on the Earth are needed to determine where and when to aim the antenna. In some embodiments, a plurality of ground stations such as ground station 500 can be arranged at different locations to increase the frequency of ground-station overpasses.

Ground station 500 includes one or more radio transmitters 505 and one or more radio receivers 506. Shown is a combiner 504 which may be a diplexer, duplexer, or transmit/receive switch or similar device. The selection of combiner is based on radio frequency (RF) design principles known in the art. For example, if the transmitter and receiver operate at different frequencies, a diplexer may be selected. Additional elements, such as power amplifiers and low-noise amplifiers, may be incorporated into the transmitter 505 and receiver 506. The transmitter 505 and receiver 506 are connected to, and are under the control of, computer(s) 507. Computer(s) 507 may be one or multiple computers and may be any combination of computers, such as desktop computers, servers, and small specialized computers such as a Raspberry Pi. Storage 508 can include information about satellite orbits, so that the rotor can be properly aimed at the right time, a schedule of satellites with which to attempt communications, data and/or commands to send to each satellite, and data received from each satellite. Through an Internet connection 509, the ground station 500 can share data, receive new commands, and generally coordinate with a central management center and/or other ground stations. Note that any networking technology can be used, with the Internet being but one example.

FIGS. 6A-C illustrate examples of a constellation of satellites, each of which carries a TDIP 300. That is, each satellite is akin to Satellite 101 carrying a TDIP 300.

In FIG. 6A, satellite 1 604 has moved in its orbit (indicated with a dashed line) and has made three plasma-density measurements 606. Each measurement is made in a manner similar to that shown in FIG. 2. In this example, satellite 1 604 is making relatively infrequent measurements (e.g. once every 10 minutes) to save power. As it did so, it passed through plasma anomaly 607. In this example the anomaly 607 is a region of high-density plasma due to a coronal mass ejection. The second and third measurements 606 were made inside the anomaly 607. Based on, e.g., either a higher-than-expected level of plasma density at measurements 2 or 3 or a higher-than-expected difference between measurement 2 and measurement 1, the TDIP 300 inside satellite 1 604 concludes that the incident is worthy of a ground alert. Through the process described in connection with FIG. 4, it communicates the ground alert, ultimately resulting in the alert being transmitted to ground station 1 601. Functioning in a manner akin to that shown in FIG. 5, ground station 1 601 receives the ground alert and forwards it to control center 603 via an Internet connection. Control Center 603 may be co-located with a ground station, such as ground station 1 601, or may be a separate facility. Control center 603, via either automated or manual means, concludes that the alert is significant and requires further, more detailed measurements. It transmits an updated set of commands to ground station 2 602. It does so because the control center, like both ground stations, knows the orbit of each satellite and knows that satellite 2 605 will soon pass over ground station 2 602 and will subsequently pass through the same (or similar) region of space that satellite 1 604 passed through earlier. Ground station 2 602 sends the updated commands to the satellite 2 605 once satellite 2 605 passes in range of ground station 2 602. In the manner described in FIG. 4, the updated commands are forwarded to the TDIP 300 on board satellite 2 605.

In FIG. 6B, satellite 2 605 has progressed in its orbit to ground station 1 601. Prior to doing so (and after having passed over ground station 2 602), satellite 2 605 executed the updated command which, in this example, instructed it to make much more frequent measurements 610 (e.g. once per second) instead of the original plan (e.g. once every 10 minutes). In this example, satellite 2 605 was instructed to make more frequent measurements 610 for a fixed amount of time (e.g. for 20 minutes) before reverting back to a slower measurement rate. As satellite 2 605 passes over ground station 1 601, it downloads the much more detailed measurement data for analysis.

In the example, satellite 2 605 had to downlink 1200 measurements (once per second for 20 minutes), consisting of either 7.2 Megabytes of time-domain data or 2.2 kilobytes of plasma-density data. Since the downlink on satellite 2 605 may be used for other purposes, such as photographs, the satellite operator may find the downlink of time-domain data undesirable because it consists of larger amounts of data that takes up significant bandwidth to transmit. There is therefore a tension between the scientific and meteorological need for detailed plasma data (7.2 Megabytes) and the need to minimize radio bandwidth.

In the example, the plasma anomaly 607 moved in space between the time of the passage of satellite 1 604 and satellite 2 605. Because the instructions sent to satellite 2 605 were based on only a single pass through the plasma anomaly 607, the operator of the satellites had no ability to estimate this motion. That is, the single set of data from satellite 1 604 did not supply enough information to make this determination, and so the high-resolution measurements are offset from the actual position of the anomaly. However, once the data from satellite 2 605 arrives, the motion of plasma anomaly 607 can be determined.

To continue the example, satellite 3 608 receives another set of instructions, taking into account the motion of plasma anomaly. As seen in FIG. 6C, its high-resolution measurements 612 are able to “get ahead” of plasma anomaly 607 and so it is able to make measurements 612 both of the anomaly and the region surrounding it. As was the case with satellite 2 605, the downlink of data from satellite 3 608 is governed by circumstances such as the urgency of the plasma data, the satellite's other data needs, etc. In this example, data from one satellite was used to adjust the measurements of another satellite. Similarly, data from a plasma forecast may be used to adjust the measurements of a satellite. In one alternate embodiment, instructions to change the measurements come from the ground station, as in the previous example, but the instructions arise from data produced by a forecast and/or nowcast model rather than data produced by a satellite. In another alternate embodiment, a satellite may be running its own forecast and/or nowcast model and may use the model to update its own measurement parameters.

FIG. 7 is an illustration of methods associated with the application of data compression. Steps 205-208 represent a typical method for a TDIP to perform a plasma measurement. Each step produces data; the data is used by subsequent steps and can optionally be stored for later transmission to Earth.

In one example, a time-domain response is received as a result of step 206 and the response can be represented as a set of time domain data 701. Besides passing the data to step 207 for further analysis, there are three steps that can be taken with the data.

First, it can be stored in uncompressed form in storage.

Second, the data can be compressed prior to storage.

Algorithms for compression are known in the art, including a polynomial fit to the data, storing the peaks (i.e. local minima and maxima) in the data, storing the zero crossings, and fitting some sort of damped sinusoid. Note that data compression can be applied by executing software on a CPU or GPU, through the use of dedicated hardware to accelerate data-compression calculations, or some combination. Most data-compression algorithms have a trade-off between compression efficiency and accuracy of the results. For example, a higher degree of data compression generally results in a compressed waveform that is more unlike the original. Because of this trade-off, the correct amount of data compression should be selected based on circumstances. In one embodiment, the compressed data is uncompressed and compared to the original. The differences between the uncompressed data and the original data can be analyzed to determine the effectiveness of the data compression and subsequently used to select either a different compression algorithm or a different degree of data compression. The analysis and selection process can be aided by artificial intelligence/machine learning methods.

Third, the data can be discarded.

The three possibilities are not mutually exclusive. For example, data may be stored in uncompressed form. Later, if it is determined that the data is of special value, it can be transmitted in uncompressed form. Alternatively, it may be decided that the data is of moderate value, in which case it is fetched from storage, compressed, and returned to storage in compressed form. One alternate embodiment would be to fetch the uncompressed data from storage and compress it for transmission out of the TDIP to other elements of the satellite, skipping the second storage step. Alternatively, it may be decided later that the data is of routine value, not worthy of transmission, and can be deleted. In other words, the level of compression, and even the decision whether to transmit at all, can be selective, based on the locally estimated significance of the data.

In some embodiments, the compression can be applied by the satellite bus, such as by C&DH computer 111, and selectively, based on the availability of radio bandwidth.

In some embodiments, later measurements can be used to determine the significance of early measurements. In the example in FIG. 6, a rate-of-change detection is only possible if two measurements are compared, and the significance of the first only becomes clear when subtracted from the second. The interaction between aspects of the measurement are important to note-the rate of change in the plasma-density measurement may indicate that the time-domain data is valuable. Because of this, uncompressed data may be stored transiently until its significance is established later, at which time selective data compression is applied. It may also be the case that the satellite sends down a digest or catalog of data, or a highly compressed data summary, and the ground station may indicate which data to send uncompressed, send compressed, or not send at all.

As with time-domain data, frequency-domain data 703 may be compressed at step 704, and the same alternatives apply. Algorithms to compress this data can be selected based on known methods in the art and the typical shape of a frequency-domain curve, including fitting a polynomial and storing local maxima and minima. Once again, compression can be applied by executing software on a CPU, through the use of dedicated hardware to accelerate data-compression calculations, or some combination of the two.

The plasma measurement 705 requires different processing steps. Because it is a single (e.g.) 15-bit measurement, compression is impractical. However, by accumulating multiple plasma measurements, in effect turning the plasma measurement into a waveform over time, it becomes possible to fit a curve to the time series of data. Hence the measurements are accumulated in step 706 before applying data compression at step 707. Again, methods are known in the art to perform the compression, including fitting a polynomial. For example, in some embodiments, the compression can include approximating the accumulated plasma measurements as a polynomial function. Compression can be applied by executing software on a CPU, through the use of dedicated hardware to accelerate data-compression calculations, or some combination of the two.

Compression can also be applied in a partial or hybrid manner. For example, most data can be highly compressed with an occasional measurement or data set transmitted with less compression. In one hybrid embodiment, one less-compressed (or uncompressed) measurement is sent and subsequent measurements can be sent as differences from the one measurement. Similarly, two less-compressed or uncompressed measurements can be sent, and the measurements in between represented as differences from the trendline. Note that the discussion of application of data compression applies to any sensor that generates a significant amount of measurement data, not just a TDIP. For example, a frequency-sweep probe may generate the same amount of data and so require data compression.

As explained above, the uncompressed measurements may be used to make decisions about the value of the data, to detect exceptional events, etc. This is shown in the Monitor Measurements step 709.

The step of monitoring measurements 709 can be used for a variety of purposes. For example, it can be programmed to detect measurement events that indicate imminent satellite danger or, conversely, that the satellite is passing out of danger. For example, a relatively high plasma density reading may indicate a higher possibility of damaging radiation or may indicate the satellite is more likely to experience drag and move into a lower orbit. In other words, the analysis can be used for the benefit of the satellite and to issue host alerts. It can be programmed to detect unusual or unexpected events that need to be transmitted down to earth and to issue ground alerts. Unusual levels of plasma, unusual rates of change of plasma, or plasma levels significantly different from those expected can be programmed to trigger host or ground alerts. At least some of the commands and parameters 401 transmitted to the TDIP can be used to set and manage alerts.

The algorithms to monitor measurements and issue alerts can be algorithms executed on a CPU, such as by comparing measurements to a threshold or comparing a difference in measurements to a threshold. Alternatively, artificial intelligence/machine learning algorithms, known in the art, could be applied. Such algorithms may run on a CPU, on a GPU, on neuromorphic computers, or even using analog computing.

Satellite 101 and ground station 500 may be owned and operated by different companies. In fact, components of satellite 101 might be owned by different companies. For example, one company may own and operate the satellite bus, another company may own and operate a camera on the satellite, a third company's ground station is used to receive the images, and a fourth company stores and sells the imagery. In other words, the space industry has a wide variety of economic arrangements.

The owner of the TDIP may, for example, want to sell the data that it gathers. In such a case, the owner may want to protect the data from the satellite owner's and the ground station operator's unauthorized use or protect the data from unauthorized eavesdropping of the downlink. Thus, the TDIP can apply encryption to measurement data before it is transmitted over communications bus 113 to the rest of the satellite. For example, it may encrypt the message for decryption by the ground station 500 or by control center 603 or by some other party.

The TDIP may also apply selective encryption. For example, it may encrypt time-domain measurements but not plasma-density measurements. It may encrypt most plasma-density measurements but allow one out of 20 to be unencrypted. Hence the satellite operator would have access to some, relatively infrequent data and paying customers would have access to more, more frequently sampled data. The nature and frequency of encryption can be dictated by business arrangements and/or by the urgency of the data. For example, ground alerts may be unencrypted.

To accomplish end-to-end encryption, TDIP can negotiate with the decrypting entity using known methods such as Diffie-Hellman key exchange or digital certificates. It can use known techniques such as TLS or SSL, known in the art for Web browsers. Other techniques, whether known or proprietary, may be used. The negotiation process may be modified to tolerate infrequent contact with different ground stations, such as by use of a relatively persistent session key. TDIP may have secure storage and/or secure element (not shown) for keys or certificates. To accomplish encryption, it may execute algorithms on a CPU, a secure element, or cryptographic acceleration hardware, or some combination of the three. In one embodiment, the TDIP uses encryption to send information to other satellite 101 elements such as C&DH computer 111, and the satellite element performs decryption. This arrangement would conceal the data from other parts of the satellite. In other embodiments, the decrypting entity may be ground station 500 or some other station or server connected to ground station 500 via its Internet connection 509.

Alternatively, through proper contractual arrangements with the owner or operator of satellite 101 the above-listed encryption techniques could be applied by the satellite, such as by C&DH computer 111. Likewise, such encryption techniques could be applied by ground station 500. In either case, the encryption can be accomplished through software executing on a CPU, through use of cryptographic acceleration hardware, or a combination of the two.

Commands and parameters sent to the TDIP, such as commands and parameters 401 may be cryptographically protected. Protection may include e.g. encryption, to provide confidentiality, and e.g. digital signatures, to provide message integrity. As with encryption, the TDIP may employ a CPU executing instructions, a secure element, cryptographic hardware acceleration, or some combination of the three.

The deployment of multiple TDIP sensors, such as on a constellation of satellites, permits the collection of data for the purposes of developing both a real-time map (a so-called “nowcast”), e.g. of plasma density and/or temperature, and a forecast. This can be accomplished by, first, sending data from multiple TDIP sensors to a central facility. The facility can, second, gather the data and use known methods, such as physical simulation using systems of partial differential equations, electromagnetic simulations, and Legendre polynomials, to interpolate the measured data in a physically plausible manner. Interpolation is needed to convert measured data, sampled at the locations and times of individual satellites, to global data, a map of plasma essentially around the entire Earth and at multiple altitudes. The models may be tied to an Earth-centered frame of reference, a solar or ephemeral frame of reference, or a sidereal frame of reference. The models may also use artificial intelligence/machine learning algorithms to perform interpolation and/or forecasting. The models may also use known solar behavior and events to improve the accuracy of the nowcast and/or forecast. In an alternate embodiment, a single satellite may run its own nowcast and/or forecast model and use the model to update its own measurement parameters.

Care should be taken to convert the satellite data, which is sampled intermittently from a moving Lagrangian pathline, to an Eulerian formulation, such as a grid representing the entirety of space near Earth. Weather forecasting has a similar issue (relatively sparse sampling of data and a Lagrangian/Eulerian conversion step) but has the advantage of fixed weather stations and fixed measurement times. Here, the nowcast and forecast will need to take into account the fact that the sampling stations are moving through space and time, and with varying measurement cadence.

One way to improve the accuracy of the nowcast and/or forecast is to manage the sampling rate and sampling locations of individual satellites. For example, in FIG. 6, it is possible that known behavior of the nowcast and forecast models, such as known uncertainties, can be used to optimize the measurement placement, measurement cadence, outgoing waveform selection, and data compression applied to measurements. Likewise, knowledge of an incoming solar coronal mass ejection can be used to manage waveform, measurement cadence, measurement placement, and data compression. The known behaviors (strengths and weaknesses) of the nowcast and forecast models can also be used to set alert thresholds. For example, a pattern of plasma-density variation may be known to be poorly handled by a model, and so detecting such a pattern may flag the need for less data compression. As another example, a pattern of plasma-density variation that may be known to be poorly handled by a model could be handled by altering the waveform used to make the measurement.

It is noted that the above-listed techniques, including, for example, software control of measurement parameters, data compression, encryption, collection of data from multiple satellites, and creation of a nowcast or forecast, can work together and be used in various combinations as needed. Physical model accuracy, contractual arrangements, availability of bandwidth, and related issues can be used to manage the individual techniques as needed.

Importantly, a satellite equipped with a TDIP sensor (or other type of plasma-density sensor, such as a frequency-sweep sensor) makes a measurement at a single point in space and time. As shown in FIG. 8A, each satellite makes measurements in situ (such as satellite 1 604 and satellite 2 605 making individual plasma-density measurements 802) and therefore in close proximity to each satellite as the measurement is being made. Each measurement occurs at a specific location and at a specific time (e.g. coordinates x, y, z, and t, or, equivalently, along a known orbit at time t). In contrast, and as shown in FIG. 8B, measurements using radio occultation are cumulative across the line of travel of the radio signal. Total electron count measurements 801 are using radio occultation between satellites (e.g. satellite 1 604 and satellite 2 605) or between a satellite and a ground station (e.g. satellite 1 604 and ground station 601). Since the measurement is accumulated over the length of the path, the measurement is not of a specific point in space. A wide-area model of plasma density, both a nowcast and a forecast, can potentially be more accurate by using point-based measurements. At least one reason is that a point-based measurement system, such as TDIP, can explore the interior of plasma anomalies in detail, as shown in FIG. 6C.

The embodiments and examples described above are presented to illustrate and explain the present disclosure and to enable persons of ordinary skill in the art to make and use embodiments of the present disclosure. However, such persons will recognize that the embodiments and examples are for illustration and example only, and are not intended to be exhaustive or to limit the scope and spirit of the present disclosure or of the following claims.

Although references have been made herein to TDIP sensors and other types of plasma-density sensors (e.g., frequency-sweep sensors), it will be appreciated that the disclosed systems and methods can be applied with various types of sensors to, for example, manage the operation of such a sensor (to, for example, improve data handling by providing selective encryptions and/or selective compression) and/or manage the operation of multiple such sensors in a constellation of satellites, in accordance with the disclosed subject matter.

It will be appreciated that the modules, processes, systems, and sections described above can be implemented in hardware, hardware programmed by software, software instructions stored on a nontransitory computer readable medium or a combination of the above. A system as described above, for example, can include a processor configured to execute a sequence of programmed instructions stored on a nontransitory computer readable medium. For example, the processor can include, but not be limited to, a personal computer or workstation, a single board computer, or other such computing system that includes a processor, microprocessor, microcontroller device, or is comprised of control logic including integrated circuits such as, for example, an Application Specific Integrated Circuit (ASIC), a field programmable gate array (FPGA), a graphics processing unit (e.g., GPGPU or GPU) or the like. The instructions can be compiled from source code instructions provided in accordance with a programming language such as Java, C, C++, C#.net, assembly or the like. The instructions can also comprise code and data objects provided in accordance with, for example, the Visual Basic™ language or another structured or object-oriented programming language, assembly language, machine language, or another programming language. The sequence of programmed instructions, or programmable logic device configuration software, and data associated therewith can be stored in a nontransitory computer-readable medium such as a computer memory or storage device which may be any suitable memory apparatus, such as, but not limited to ROM, PROM, EEPROM, RAM, flash memory, disk drive and the like.

Furthermore, the modules, processes systems, and sections can be implemented as a single processor or as a distributed processor. Further, it should be appreciated that the steps mentioned above may be performed on a single or distributed processor (single and/or multi-core, or cloud computing system). Also, the processes, system components, modules, and sub-modules described in the various figures of and for embodiments above may be distributed across multiple computers or systems or may be co-located in a single processor or system. Example structural embodiment alternatives suitable for implementing the modules, sections, systems, means, or processes described herein are provided below.

The modules, processors or systems described above can be implemented as a programmed general purpose computer, an electronic device programmed with microcode, a hard-wired analog logic circuit, software stored on a computer-readable medium or signal, an optical computing device, a networked system of electronic and/or optical devices, a special purpose computing device, an integrated circuit device, a semiconductor chip, and/or a software module or object stored on a computer-readable medium or signal, for example.

Embodiments of the method and system (or their sub-components or modules), may be implemented on a general-purpose computer, a special-purpose computer, a programmed microprocessor or microcontroller and peripheral integrated circuit element, an ASIC or other integrated circuit, a digital signal processor, a hardwired electronic or logic circuit such as a discrete element circuit, a programmed logic circuit such as a PLD, PLA, FPGA, PAL, GP, GPU, or the like. In general, any processor capable of implementing the functions or steps described herein can be used to implement embodiments of the method, system, or a computer program product (software program stored on a nontransitory computer readable medium).

Furthermore, embodiments of the disclosed method, system, and computer program product (or software instructions stored on a nontransitory computer readable medium) may be readily implemented, fully or partially, in software using, for example, object or object-oriented software development environments that provide portable source code that can be used on a variety of computer platforms. Alternatively, embodiments of the disclosed method, system, and computer program product can be implemented partially or fully in hardware using, for example, standard logic circuits or a VLSI design. Other hardware or software can be used to implement embodiments depending on the speed and/or efficiency requirements of the systems, the particular function, and/or particular software or hardware system, microprocessor, or microcomputer being utilized. Embodiments of the method, system, and computer program product can be implemented in hardware and/or software using any known or later developed systems or structures, devices and/or software by those of ordinary skill in the applicable art from the function description provided herein and with a general basic knowledge of the software engineering and computer networking arts.

Moreover, embodiments of the disclosed method, system, and computer readable media (or computer program product) can be implemented in software executed on a programmed general purpose computer, a special purpose computer, a microprocessor, or the like.

It is, therefore, apparent that there is provided, in accordance with the various embodiments disclosed herein, methods, systems and computer readable media for space weather measurement.

While the disclosed subject matter has been described in conjunction with a number of embodiments, it is evident that many alternatives, modifications and variations would be, or are, apparent to those of ordinary skill in the applicable arts. Accordingly, Applicants intend to embrace all such alternatives, modifications, equivalents and variations that are within the spirit and scope of the disclosed subject matter.

What is claimed is:

1. A system for measuring a physical phenomenon using a plurality of satellites, the system comprising:
a controlling station; and
a first satellite comprising:
a communication interface;
a command and data handling computer;
a probe device;
the command and data handling computer being coupled to the communication interface, the command and data handling computer comprising a processor and a memory coupled to the processor, the memory storing instructions that, when executed by the processor, cause the command and data handling computer to perform command and data handling operations comprising:
receiving, from the controlling station, first measurement parameters;
providing, using the communication interface, the first measurement parameters to the probe device;
the probe device being coupled to the communication interface, the probe device comprising a processor and a memory coupled to the processor, the memory storing instructions that, when executed by the processor, cause the probe device to perform probe device operations comprising:
receiving, using the communication interface, the first measurement parameters;
measuring the physical phenomenon using the first measurement parameters and collecting measurement data;
processing the collected data;
applying data compression selectively to the processed collected data based on one or more of the first measurement parameters and/or a determined significance of the processed collected data;
applying encryption selectively to the processed collected data with the selectively applied data compression to generate selectively compressed and selectively encrypted measurement data; and
transferring, using the communication interface, the selectively compressed and selectively encrypted measurement data to another device on the satellite, wherein the another device is configured to transmit to the controlling station the selectively compressed and selectively encrypted measurement data;
the controlling station comprising an antenna and a controlling station computer, the controlling station computer comprising a processor and a memory coupled to the processor, the memory storing instructions that, when executed by the processor, cause the controlling station computer to perform controlling station operations comprising:
transmitting the first measurement parameters to the first satellite;
receiving the selectively compressed and selectively encrypted measurement data from the first satellite;
analyzing the selectively compressed and selectively encrypted measurement data to determine the existence of an anomaly at one or more locations in space;
determining one or more second measurement parameters different from the said first measurement parameters, the determining being based at least in part on the analyzing and the second measurement parameters being configured to cause a second satellite to perform additional measurements targeting the anomaly, and
transmitting the second measurement parameters to the second satellite, the second satellite being configured to perform additional measurements targeting the anomaly based on the second measurement parameters.

2. The system of claim 1, wherein the physical phenomenon comprises plasma density.

3. The system of claim 1, wherein the physical phenomenon comprises plasma temperature.

4. The system of claim 1, wherein the probe device is a time-domain impedance probe (TDIP).

5. The system of claim 1, wherein the analyzing comprises generating or updating a forecast model based on the data received from the first satellite.

6. The system of claim 5, wherein the controlling station operations further comprise:
receiving, from the second satellite, data collected and processed by the second satellite, wherein the second satellite is configured to collect and process the data based on one or more of the second measurement parameters and/or a determined significance of the processed collected data.

7. The system of claim 6, wherein the controlling station operations further comprise:
updating the forecast model based on the data received from the second satellite; and
generating an alert based on the updated model.

8. A method for measuring a physical phenomenon using an instrument housed on a satellite, the method comprising performing, by the instrument, operations comprising:
receiving measurement parameters transmitted by a ground station;
measuring the phenomenon using the measurement parameters by collecting data;
processing the collected data;
applying data compression selectively to the processed collected data as indicated by the measurement parameters;
applying encryption selectively to the processed collected data as indicated by the measurement parameters; and
transferring, to another portion of the satellite, the processed collected data with the data compression selectively applied and with the encryption selectively applied.

9. The method of claim 8, wherein the physical phenomenon comprises plasma density.

10. The method of claim 8, wherein the physical phenomenon comprises plasma temperature.

11. The method of claim 8, wherein the another portion of the said satellite is configured to transmit the processed collected data with the data compression selectively applied and with the encryption selectively applied to a ground station.

12. The method of claim 8, wherein the instrument includes automatic amplitude control and/or self-calibration.

13. A method for measuring a physical phenomenon using instruments housed on a plurality of satellites, the method comprising:
receiving, from a control center, a first set of measurement parameters at a first instrument housed on a first satellite;
measuring, by the first instrument, the phenomenon using the first set of measurement parameters by collecting data;
processing, by the first instrument, the collected data into processed data;
transferring the processed collected data to another device of the satellite, wherein the another device is configured to transmit the processed collected data to a first ground station, wherein the first ground station is configured to transmit the processed collected data to the control center, the control center being configured to perform operations comprising:
analyzing the processed collected data, and
determining a second set of measurement parameters different from the said first set of measurement parameters, the determining being based at least in part on the analyzing the processed collected data, and
receiving, from a second ground station or the first ground station, the second set of measurement parameters at a second instrument housed on a second satellite; and
measuring, by the second instrument, the phenomenon using the second set of measurement parameters by collecting data.

14. The method of claim 13, wherein the physical phenomenon comprises plasma density.

15. The method of claim 13, wherein the physical phenomenon comprises plasma temperature.

16. The method of claim 13, wherein the step of processing, by the first instrument, the collected data comprises selective data compression.

17. The method of claim 13, wherein the step of processing, by the first instrument, the collected data comprises selective encryption.

18. The method of claim 13, wherein the control center is different from the first ground station and the control center is different from the second ground station.

19. The method of claim 13, wherein the control center is the same as either the first ground station or the second ground station.

20. The method of claim 13, wherein the first and second instruments include automatic amplitude control and/or self-calibration.
